(19) United States
(12) Patent Application Publication
(10) Pub. No.: US 2006/0192487 A1
(43) Pub. Date: Aug. 31, 2006

(54) Display device and fabricating method thereof

(75) Inventors: Beohm-Rock Choi, Seoul (KR); Hoon Kim, Suwon-si (KR); Un-Cheol Sung, Anyang-si (KR)

Correspondence Address: Edwrad C. Kwok;MacPHERSON KWOK CHEN & HEID LLP, Suite 226, 1762 Technology Drive, San Jose, CA, 95110, US

(73) Assignee: SAMSUNG ELECTRONICS CO., LTD., Suwon-si (KR)

(21) Appl. No.: 11/150,617

(22) Filed: Jun. 10, 2005

(30) Foreign Application Priority Data
Feb. 25, 2005 (KR) 2005-16058

(51) Int. Cl. H05B 33/04; H05B 33/10

(52) U.S. Cl. 313/512; 445/25

(57) ABSTRACT

A display device includes a first substrate, light emitting elements formed over the first substrate, a second substrate facing the first substrate, and a sealing member between the first and the second substrate to combine them. The sealing member is patterned to expose the light emitting elements. The sealing member may include black colored material to improve contrast, and dehydrating material may be part of the device to absorb moisture and/or oxygen. Accordingly, the transmittance of light generated from the light emitting elements increases and the luminance of display device improves.

### CROSS-REFERENCE TO RELATED APPLICATION

This application claims priority to Korean Patent Application No. 2005-016058 filed on Feb. 25, 2005.

### BACKGROUND

1. Field of the Invention

The present invention relates generally to a display device and a method of fabricating the same, and in particular to an organic light emitting display (OLED) device and a method of fabricating the same.

2. Description of Related Art

Consumers, in general, want electronic devices with displays, such as mobile communication systems, digital cameras, notebook PCs, monitors, and televisions, to be light and thin. One method of achieving this is to use flat panel displays, such as ones having an organic light emitting display (OLED).

An OLED is self-emissive. OLEDs have desirable characteristics such as a relatively wide viewing angle and a relatively high contrast ratio as compared to liquid crystal displays (LCDs). Further, because an OLED does not require a backlight assembly, OLEDs are lighter and consume less power than LCDs. Other advantageous features include a fast response time, a wide range of operating temperatures, and low manufacturing cost.

However, the light-emitting layer of OLEDs includes organic material, which may react to moisture and/or oxygen to change chemical and electronic properties of the organic material. This may result in the OLED having degraded image quality and a reduced life time. Thus, there is a need for OLEDs that are less susceptible to moisture and oxygen.

### SUMMARY OF THE INVENTION

According to one aspect of the present invention, a display device includes a first substrate, a second substrate facing the first substrate, a plurality of light emitting elements over the first substrate, and a sealing member between the first substrate and the second substrate. The sealing member combines the first substrate and the second substrate and has portions to expose the light emitting elements.

The sealing member surrounds each light emitting element or some light emitting elements. The display device can also include a partition member between the light emitting elements. The sealing member is formed over only the partition member in one embodiment. Also, the sealing member can be formed over only some partition members. The sealing member is formed of a photo-curable resin or tape, or thermo-setting resin or tape. The sealing member can further include black-colored material to improve contrast ratio of the display device.

The display device further includes an optional dehydrating layer between the second substrate and the light emitting elements. The dehydrating layer substantially covers the second substrate. The dehydrating layer can be formed only above the sealing member. Also, the dehydrating layer can be formed only over the light emitting elements to remove moisture and/or oxygen.

A method of manufacturing a display device according to one aspect of the present invention includes forming a plurality of light emitting elements over a first substrate, forming a sealing member over the first substrate, exposing the light emitting elements through the sealing member, aligning a second substrate with the sealing member, and combining the first substrate and the second substrate. Combining the first substrate and the second substrate includes curing the sealing member by light or heat. The method can further include forming a protection layer over the light emitting elements. Also, the method of the display device can include forming a dehydrating layer on the second substrate.

According to another aspect of the present invention, a method of manufacturing a display device includes forming a plurality of light emitting elements over a first substrate, forming a sealing member over a second substrate having portions exposing areas of the second substrates, aligning the second substrate so that the portions overlie the light emitting elements, and combining the first substrate and the second substrate.

According to another aspect of the present invention, a method of manufacturing a display device includes forming a plurality of light emitting elements over a first substrate, forming a first sealing member over the first substrate, forming a second sealing member over a second substrate, aligning the first sealing member with the second sealing member, and combining the first substrate and the second substrate so that light from the light emitting elements can pass through the second substrate.

### BRIEF DESCRIPTION OF THE DRAWINGS

The features of the present invention will become more apparent to those of ordinary skill in the art by describing in detail exemplary embodiments thereof with reference to the attached drawings, in which:

FIG. 1 is a plan view of a display device according to an embodiment of the present invention;

FIG. 2 is a cross-sectional view taken along the line A-A′ of the display device of FIG.1;

FIG. 3 is a cross-sectional view of a display device according to another embodiment of the present invention;

FIG. 4 is a cross-sectional view of a display device according to another embodiment of the present invention;

FIG. 5 is a flow chart showing processes of fabricating the display device of the present invention according to one embodiment;

FIGS. 6 to 10 are cross-sectional views showing a method of fabricating a display device according to the flow chart of FIG. 5;

FIG. 11 is a flow chart showing another process of fabricating a display device of the present invention according to one embodiment;

FIG. 12 is a flow chart showing another process of fabricating a display device of the present invention according to one embodiment; and

FIG. 13 is a cross-sectional view of a display device fabricated by the flow chart of FIG. 12.

Use of the same reference symbols in different figures indicates similar or identical items.

### DETAILED DESCRIPTION OF PREFERRED EMBODIMENTS

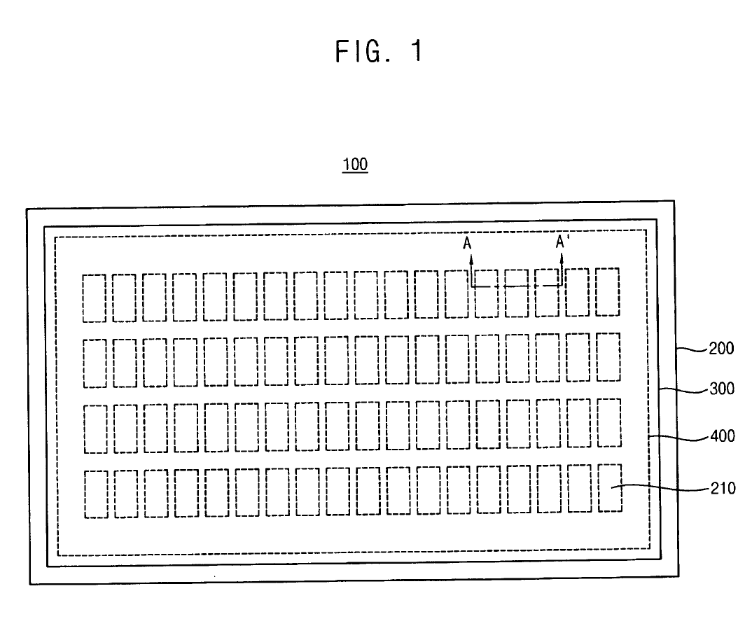

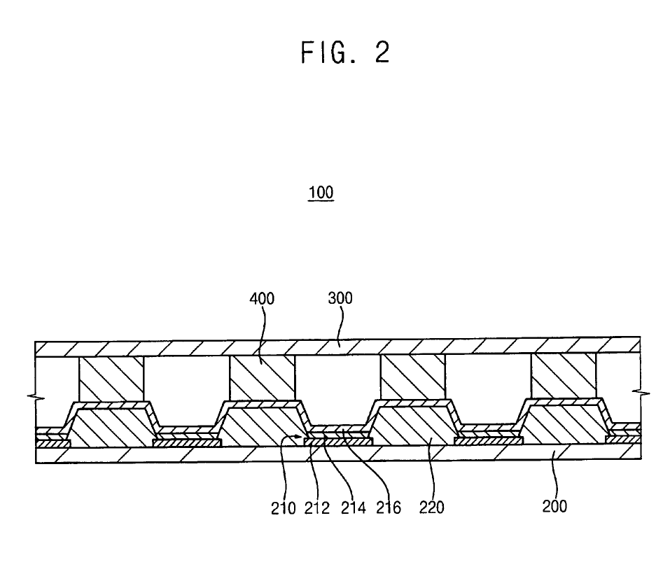

FIG. 1 is a plan view of a display device 100 according to an embodiment of the present invention and FIG. 2 is a cross-sectional view taken along the line A-A′ of FIG. 1.

Referring to FIGS. 1 and 2, display device 100 includes a first substrate 200, a second substrate 300, and a sealing member 400. First substrate 200 is transparent, such as glass, or opaque. Also, first substrate 200 may be flexible or rigid.

Light emitting elements 210 are formed on first substrate 200 and arranged in a matrix (FIG. 1), such as 1024×768. Light emitting elements 210 are organic light emitting elements, where each light emitting element 210 can form a pixel.

Second substrate 300 is disposed over first substrate 200 and light emitting elements 210 and is combined with first substrate 200 by sealing member 400 located in between. Second substrate 300 prevents external moisture and/or oxygen from contacting and reacting with light emitting elements 210. Therefore, second substrate 300 prevents light emitting elements 210 from degrading.

Second substrate 300, which may be flexible or rigid, is transparent to light generated from light emitting elements 210. Second substrate 300 includes a material having low permeability to moisture and oxygen, such as soda-lime glass, silicate glass, boron-silicate glass, or lead glass.

The thickness of second substrate 300 is about 0.1 mm to about 10 mm. When the thickness of second substrate 300 is less than 0.1 mm, second substrate 300 may be easily broken, and moisture and oxygen may easily pass through second substrate 300. When the thickness of second substrate 300 is greater than 10 mm, display device 100 may become overly thick and heavy.

Sealing member 400 is patterned to expose light emitting elements 210. Accordingly, transmitted light increases and luminance of display device 100 improves. Sealing member 400 surrounds each of light emitting elements 210, with portions of sealing member 400 corresponding to light emitting elements 210 removed or not formed. Sealing member 400 may be formed over first substrate 200, second substrate 300, or both, such as by a screen printer, a roll printer, a slit coater, or other equipment for coating organic material.

Sealing member 400 can include a photo-curable or thermo-setting resin or a photo-curable or thermo-setting tape having a thickness of about 1μm or more. Thus, when light or heat is applied to sealing member 400, first substrate 200 and second substrate 300 are combined. Sealing member 400 may include black colored materials, such as carbon, which can be added to the resin to adjust the optical transmissivity. In one embodiment, light-transmittance is less than 70%. By adding black colored materials, the contrast ratio of device 100 is enhanced.

In some embodiments, sealing member 400 may further include a dehydrating agent or desiccant, such as calcium (Ca), barium (Ba), calcium oxide (CaO), and barium oxide (BaO), to remove moisture and/or oxygen. Referring to FIG. 2, light emitting element 210 includes a first electrode 212, an organic light emitting layer 214, and a second electrode 216. First electrode 212 is formed over first substrate 200. Organic light emitting layer 214 is formed on first electrode 212. Second electrode 216 is formed on organic light emitting layer 214.

When a voltage is applied to light emitting layer 214, light emitting layer 214 is provided electrons from first electrode 212, corresponding to a cathode, and holes from second electrode 216, corresponding to an anode. Light is generated from light emitting layer 214 when holes are combined with electrons to a lower energy state.

For example, if first electrode 212 is a cathode, it can be formed of an opaque metal, such as calcium (Ca), barium (Ba), silver (Ag), copper (Cu), aluminum (Al), magnesium (Mg) or alloys thereof. First electrode 212 may have multi-layered structure, such as a double layer. The upper layer can be formed of ITO, IZO or a-ITO, and the lower layer can be formed of a metal layer to reflect the light emitted from organic light emitting layer 214. Silver (Ag), chromium (Cr), and aluminum (Al) can be used as the lower layer. Organic light emitting layer 214 includes an organic material having a low molecular weight or a polymer. Organic light emitting layer 214 may include a light emitting layer which emits red, green, or blue light. Generally, organic light emitting layer 214 has a plurality of sub-layers, e.g., a hole-injection layer, an electron-injection layer, and a light-emitting layer. The hole-injection layer is formed on and receives holes from first electrode 212. The light-emitting layer is formed on the hole-injection layer, and the electron-injection layer is formed between the light-emitting layer and second electrode 216. The electron-injection layer receives electrons from second electrode 216.

In one embodiment, second electrode 216 is formed of transparent conductive material, such as Indium Tin Oxide (ITO), Indium Zinc Oxide (IZO), or amorphous Indium Tin Oxide (a-ITO), so that light generated from organic light emitting layer 214 can be transmitted through second electrode 216.

In another embodiment, second electrode 216 is formed of a thin metal, such as aluminum (Al), calcium (Ca), barium (Ba), magnesium (Mg), or alloys thereof, so that second electrode 216 becomes transparent An upper layer of ITO, IZO, or a-ITO, may be formed over the thin metal layer for protection.

A partition member or bank 220 is formed over first substrate 200 and between first electrodes 212 to insulate first electrodes 212 from each other. An organic or inorganic layer may be patterned to form partition member 220. For example, an organic layer including a photosensitive material is formed on first substrate 200 having first electrodes 212 formed thereon. The organic layer is then patterned to expose interior portions of first electrodes 212, while leaving insulating portions between first electrodes 212. Light emitting layer 214 is then formed over first electrodes 212.

Second electrode 216, which covers the whole area of first substrate 200 except where terminals for connecting to external circuits are formed, is formed over partition member 220 and organic light emitting layer 214. Sealing member 400 is formed over only partition member 220 to prevent absorption of light from sealing member 400 over light emitting elements 210.

Display device 100 further includes a layer of switching elements (not shown) such as thin film transistors (TFTs) over first substrate 200. Each of the switching elements is connected to first electrodes 212 and signal wiring for applying signals provided from an external device to the switching elements.

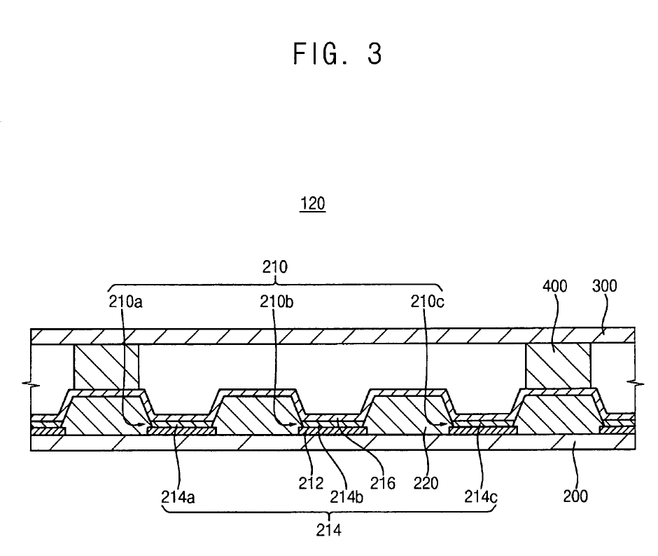

FIG. 3 shows a cross-sectional view of a display device 120 according to another embodiment of the present invention. Elements shown in FIG. 3 are identical to elements shown in FIG. 2 except the location of sealing member 400. The duplicated explanation is skipped.

In this embodiment, sealing members 400 are not located between each adjacent light emitting element or over each partition member, as with the previous embodiment. With higher resolution display devices, both the size of light emitting elements and the space between light emitting elements decrease. Accordingly, it may become difficult to form sealing members 400 between each light emitting element 210 or over each partition member 220.

Referring to FIG. 3, display device 120 includes first light emitting elements 210a, second light emitting elements 210b, and third light emitting elements 210c. Each light emitting element 210a, 210b, and 210 includes a first, second, and third organic light emitting layer 214a, 214b, and 214c, respectively. First, second, and third organic light emitting layers 214a, 214b, and 214c can be grouped together to form one pixel unit, e.g., with first organic light emitting layer 214a adjacent to second organic light emitting layer 214b and second organic light emitting layer 214b adjacent to third organic light emitting layer 214c. First, second, and third organic light emitting layer 214a, 214b, and 214c emit different colored light, e.g., red, blue, and green, respectively.

In FIG. 3, sealing member 400 is disposed around each unit pixel. However, sealing member 400 may be disposed around more or less light emitting elements, depending on various factors, such as design rules and resolution.

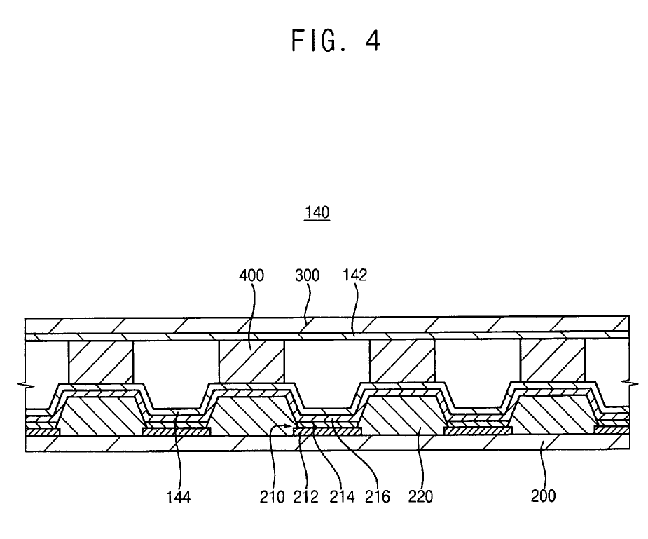

FIG. 4 is a cross-sectional view of a display device 140 according to another embodiment of the present invention. Elements shown in FIG. 4 are identical to elements shown in FIG. 3 except a dehydrating or desiccant layer 142 and a protection layer 144. Like numerals refer to like elements. The duplicated explanation is skipped.

Dehydrating layer 142 is formed on the inside surface of second substrate 300 facing light emitting elements 210. Dehydrating layer 142 is formed of a transparent material so that light generated from light emitting elements 210 can pass through. Dehydrating layer 142 includes a material to react chemically with hydrate (moisture) and oxygen to prevent external moisture and oxygen from entering into display device 140 and remove moisture and oxygen within display device 140. For example, dehydrating layer 142 includes calcium (Ca), barium (Ba), calcium oxide (CaO), and/or barium oxide (BaO).

Dehydrating layer 142 can cover the whole area or only selected portions of second substrate 300. For example, dehydrating layer 142 may be only over sealing member 400 or only over light emitting elements 210. Display device 140 further includes protection layer 144 to cover light emitting elements 210 and prevent moisture or oxygen from organic light emitting layer 214. Protection layer 144 is formed of transparent material so that light generated from light emitting elements 210 can pass through.

Protection layer 144 may include an organic layer, such as polyacetylene or polyimide. In other embodiments, protection layer 144 may include an inorganic layer, such as silicon oxide, silicon nitride, silicon oxynitride, magnesium oxide, aluminum oxide, aluminum nitride, or titanium oxide, formed by a sputter, chemical vapor deposition (CVD), or other suitable process. Protection layer 144 may have multi-layered structure where organic layer and inorganic layer alternate with each other. Protection layer 144 may further include a dehydrating material in order to remove moisture and oxygen.

Protection layer 144 can cover the whole area or only partial areas of second electrode 216. For example, protection layer 144 can be formed over the area corresponding to organic light emitting layer 214.

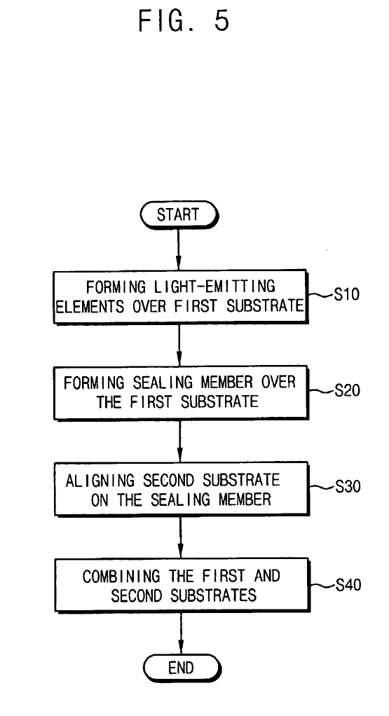

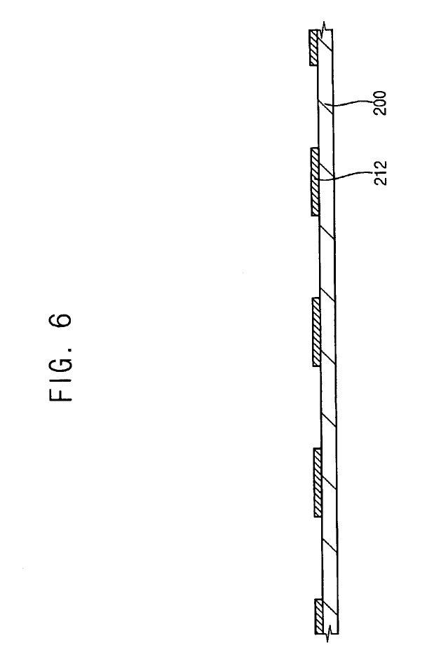

FIG. 5 is a flow chart showing a process for fabricating a display device according to an embodiment of the present invention. FIGS. 6 to 10 show cross-sectional views according to fabrication process of FIG. 5.

Referring to FIG. 5, a fabrication process includes forming light emitting elements 210 on first substrate 200 (S10), forming sealing member 400 over first substrate 200 (S20), aligning second substrate 300 on sealing member 400 (S30), and combining first substrate 200 and second substrate 300 (S40).

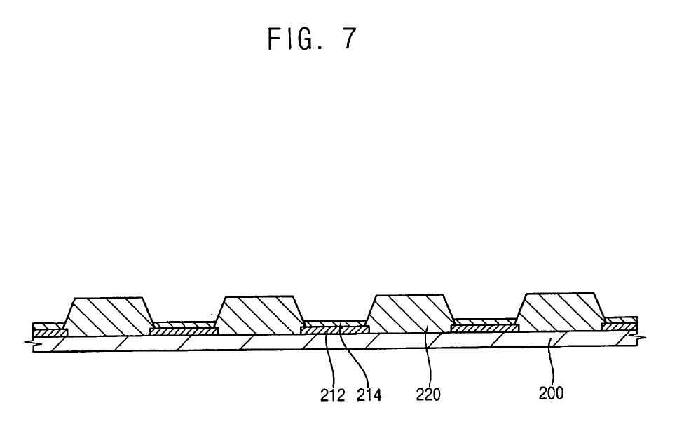

In S10 of FIG. 5, each of light emitting elements 210 includes first electrode 212, organic light emitting layer 214, and second electrode 214. Referring to FIG. 6, a plurality of first electrodes 212 are first disposed on first substrate 200 in a matrix pattern. First electrode 212 can include an opaque metal, such as calcium (Ca), barium (Ba), magnesium (Mg), silver (Ag), copper (Cu), aluminum (Al), or alloys thereof. Next, in FIG. 7, partition member 220 is formed between first electrodes 212 to cover the edges of first electrodes 212 and electrically separate first electrodes 212 from one another. Partition member 220 is formed of organic material or inorganic material. Organic light emitting layer 214 is then formed on first electrode 210. Organic light emitting layer 214 can include material of small molecular weight or a polymer and include multi-layers. For example, organic light emitting layer 214 may include a hole injection layer, the organic light emitting layer, and an electron injection layer.

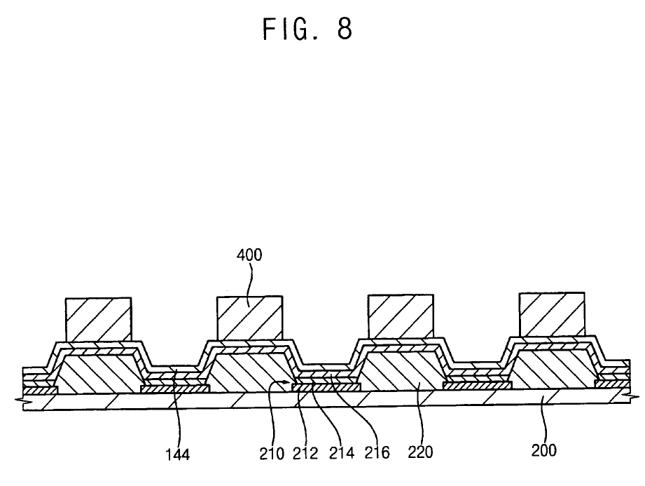

Referring to FIG. 8, second electrode 216 is formed over the whole area of first substrate 200 to cover organic light emitting layers 214 and partition members 220. Second electrode 216 can include a transparent conductive material, such as Indium Tin Oxide (ITO), Indium Zinc Oxide (IZO), or amorphous Indium Tin Oxide (a-ITO).

Protection layer 144 is optionally formed on second electrode 216 to prevent moisture and oxygen from entering display device 100. Protection layer 144 can include an organic layer, such as polyacetylene or polyimide, or an inorganic layer such as silicon oxide, silicon nitride, silicon oxynitride, magnesium oxide, aluminum oxide, aluminum nitride, or titanium oxide. Inorganic layer can be formed by a sputter, chemical vapor deposition (CVD), or other suitable process. Protection layer 144 may have multi-layered structure where organic layer and inorganic layer alternates with each other. Protection layer 144 may further include a dehydrating material to remove moisture and oxygen.

Protection layer 144 covers the whole area of second electrode 216, or alternatively, is formed over partial areas of second electrode 216, such as over the areas corresponding to organic light emitting layer 214.

In S20 of FIG. 5, sealing member 400 is formed on portions of protection layer 144 to expose light emitting elements 210. Sealing member 400 is disposed over the area where partition member 220 is disposed. Sealing member 400 is formed over only partition member 220 where light is not emitted so that loss of light generated from organic light emitting layer 214 decreases.

Sealing member 400 may surround each of light emitting elements 210, e.g. over every partition member 220, or be disposed over only some of partition members 220, depending on various factors, such as design rule or resolution of display device.

Sealing member 400 can include a photo-curable resin or a thermo-setting resin. The photo-curable resin or thermo-setting resin can be deposited over first substrate 200 by a screen printer, a roll printer, a slit coater, or other equipment for coating organic material to form sealing member 400.

A photo-curable or thermo-setting tape having thickness about 1μm or larger may be attached over first substrate 200 and used as sealing member 400.

Sealing member 400 may further include a dehydrating agent or desiccant, such as calcium (Ca), barium (Ba), calcium oxide (CaO), or barium oxide (BaO), to remove moisture and/or oxygen.

Sealing member 400 may be formed of black colored materials, such as carbon, which have light-transmittance less than about 70%. For example, carbon particles having a black color may be added to the photo-curable or thermo-setting resin to adjust the optical transmissivity. Black colored materials in sealing member 400 improve the contrast ratio of display device 100.

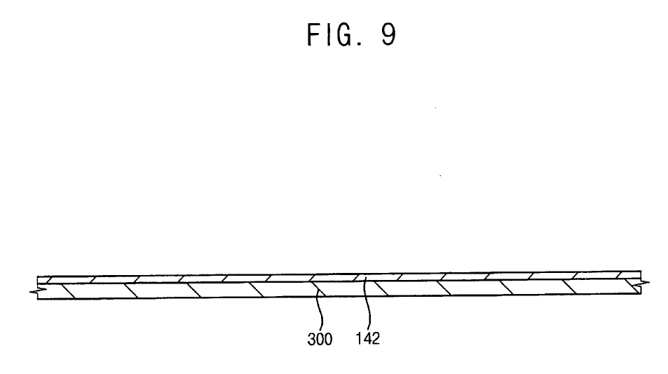

In S30 of FIG. 5, second substrate 300 is aligned over first substrate 200 having sealing member 400. Referring to FIG. 9, before second substrate 300 is aligned over first substrate 200, dehydrating layer 142 may be formed on second substrate 300. Dehydrating layer 142 is formed of a transparent material to allow light emitted from organic light emitting layer 214 of FIG. 8 to pass through. Dehydrating layer 142 includes material which can react chemically with hydrates or oxygen to remove moisture or oxygen in display device 140. For example, dehydrating layer 142 may include calcium (Ca), barium (Ba), calcium oxide (CaO), or barium oxide (BaO).

Dehydrating layer 142 covers the whole area of second substrate 300, as shown in FIG. 9. Alternatively, dehydrating layer 142 can be formed over only portions of second substrate 300, such as the areas over sealing member 400 or over light-emitting elements 210.

If dehydrating layer 142 is formed on second substrate 300, second substrate 300 is aligned over first substrate 200 so that dehydrating layer 142 faces sealing member 400.

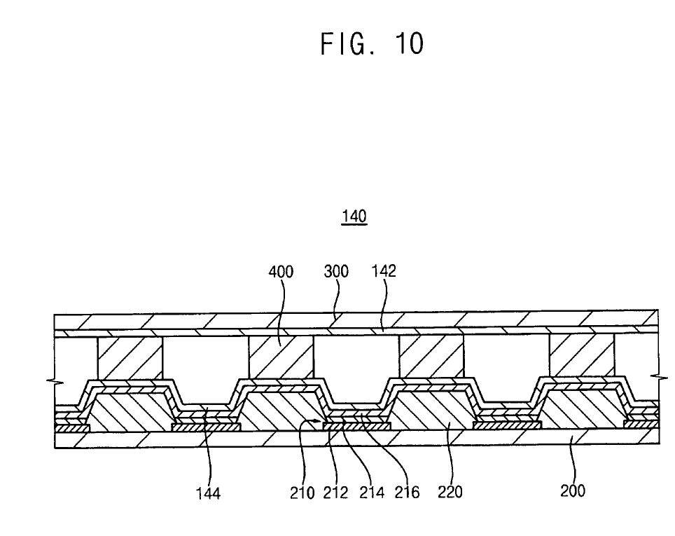

In S40 of FIG. 5, first substrate 200 and second substrate 300 are combined by applying light or heat to sealing members 400 to form display device 140 of FIG. 10. When sealing member 400 is a photo-curable resin or tape, sealing member 400 is cured by external light such as Ultra-Violet (UV) light. When sealing member 400 is a thermo-setting resin or tape, sealing member 400 is cured by external heat.

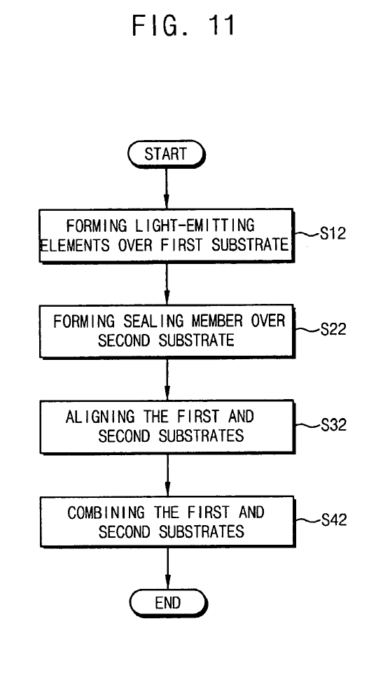

FIG. 11 is a flow chart showing a process for fabricating a display device according to another embodiment of the present invention. Display devices fabricated according to FIG. 11 have substantially the same structure as display device 140 of FIG. 10. Duplicated explanation of same elements and same processes is skipped.

Referring to FIG. 10 and FIG. 11, a fabrication process includes forming light emitting elements 210 over first substrate 200 (S12), forming sealing member 400 over second substrate 300 (S22), aligning first substrate 200 and second substrate 300 (S32), and combining first substrate 200 and second substrate 300 (S42). The fabrication process of FIG. 11 differs from the previous embodiment in that sealing member 400 is formed over second substrate 300 instead of first substrate 200. In S22 of FIG. 11, sealing member 400 is formed over second substrate 300 so that organic light emitting layer 214 is not covered by sealing member 400 when first substrate 200 and second substrate 300 are combined. An optional dehydrating layer 142 can be formed on second substrate 300 before sealing member 400 is formed.

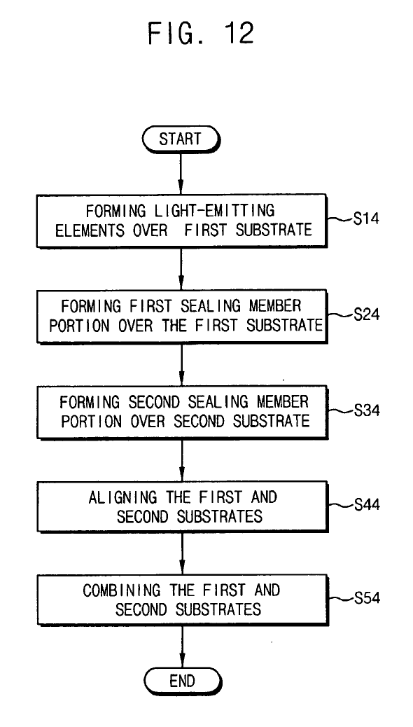

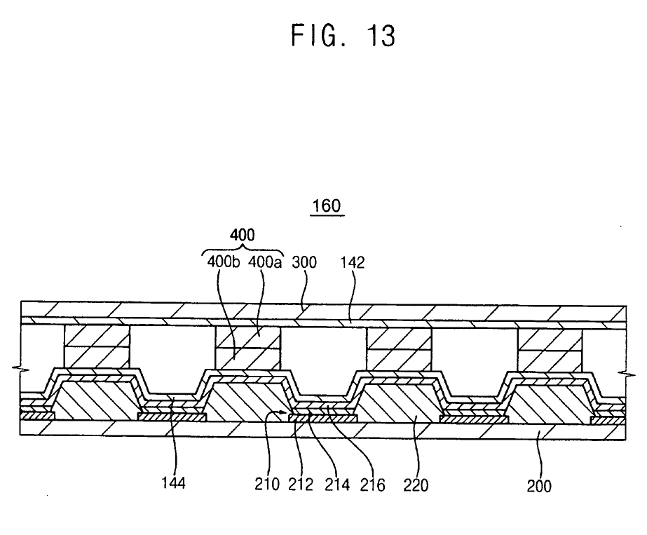

FIG. 12 is a flow chart showing a process for fabricating a display device according to another embodiment of the present invention. FIG. 13 is a cross-sectional view of a display device 160 fabricated according to of FIG. 12. Display device 160 of FIG. 13 has substantially the same structure as device 140 of FIG. 10 except the structure of sealing member 400. Sealing member 400 of display device 160 includes a first sealing member 400a and a second sealing member 400b . Duplicated explanation of same elements is skipped.

Referring to FIG.12 and FIG.13, a fabrication process includes forming light emitting elements 210 over first substrate 200 (S14), forming first sealing member 400a over first substrate 200 (S24), forming second sealing member 400b over second substrate 300 (S34), aligning first substrate 200 and second substrate 300 (S44), and combining first substrate 200 and second substrate 300 (S54).

In S24, first sealing member 400a is formed over first substrate 200 to expose light emitting elements 210. In S34, second sealing member 400b is formed over second substrate corresponding to first sealing member 400a. In S44, first sealing member 400a and second sealing member 400b are aligned to face each other. First sealing member 400a and second sealing member 400b are then combined, such as by heat or light, to join first substrate 200 and second substrate 300 in S54.

Although the invention has been described with reference to particular embodiments, the description is an example of the invention's application and should not be taken as a limitation. Various adaptations and combinations of the features of the embodiments disclosed are within the scope of the invention as defined by the following claims.

What is claimed is:

1. A display device comprising:
a first substrate;
a second substrate facing the first substrate;
a plurality of light emitting elements over the first substrate; and
a sealing member between the first substrate and the second substrate to combine the first substrate and the second substrate, wherein the sealing member has portions to expose the light emitting elements.

2. The display device of claim 1, wherein each of the light emitting elements comprises:
a first electrode over the first substrate;
an organic light emitting layer over the first electrode; and
a second electrode over the light emitting layer.

3. The display device of claim 2, further comprising an electrically insulating partition between the light emitting elements.

4. The display device of claim 3, wherein the partition covers the edges of adjacent first electrodes.

5. The display device of claim 1, wherein the sealing member comprises a photo-curable resin or thermo-setting resin.

6. The display device of claim 1, wherein the sealing member comprises a photo-curable tape or thermo-setting tape.

7. The display device of claim 1, wherein the sealing member is between light emitting elements.

8. The display device of claim 1, wherein at least two light emitting elements form a group, and wherein the sealing member is between groups.

9. The display device of claim 1, wherein at least two light emitting elements form a pixel, and wherein each light emitting element in the pixel generates a different color light.

10. The display device of claim 3, wherein the sealing member is formed over the partition member.

11. The display device of claim 1, further comprising a dehydrating layer between the second substrate and the light emitting elements.

12. The display device of claim 11, wherein the dehydrating layer substantially covers the second substrate.

13. The display device of claim 11, wherein the dehydrating layer is located only above the sealing member.

14. The display device of claim 11, wherein the dehydrating layer is located only above the portions of the sealing member over the light emitting elements.

15. The display device of claim 1, further comprising a protection layer over the light emitting elements.

16. The display device of claim 1, wherein the sealing member comprises a dehydrating material.

17. The display device of claim 1, wherein the sealing member comprises a black-colored material.

18. The display device of claim 1, wherein the sealing member has an optical transmissivity of approximately 70% or less.

19. The display device of claim 2, wherein the first electrode comprises a conductive material, and the second electrode comprises a transparent conductive material.

20. The display device of claim 3, wherein the second electrodes cover the organic light-emitting layer and the partition.

21. The display device of claim 15, wherein the protection layer comprises an organic material.

22. The display device of claim 15, wherein the protection layer comprises an inorganic material.

23. The display device of claim 15, wherein the protection layer comprises an organic layer and an inorganic layer.

24. The display device of claim 1, further comprising switching elements to transfer electric signals to the light emitting elements.

25. A method of manufacturing a display device, comprising:
forming a plurality of light emitting elements over a first substrate;
forming a sealing member over the first substrate;
exposing the light emitting elements through portions of the sealing member;
aligning a second substrate with the sealing member; and
combining the first substrate and the second substrate.

26. The method of claim 25, wherein the combining comprises hardening the sealing member.

27. The method of claim 25, wherein the sealing member is formed between the light emitting elements.

28. The method of claim 25, wherein forming a sealing member comprises depositing a photo-curable resin or a thermo-setting resin.

29. The method of claim 25, wherein forming a sealing member comprises attaching a photo-curable tape or a thermo-setting tape.

30. The method of claim 25, wherein the light emitting elements are formed in a plurality of groups, and wherein the sealing member is formed on a region between the groups.

31. The method of claim 25, wherein the light emitting elements are grouped into a plurality of pixels, each light emitting element within a pixel generating a different colored light, and wherein the sealing member is formed on a region between the pixels.

32. The method of claim 25, wherein combining the first substrate and second substrate comprises curing the sealing member by light or heat.

33. The method of claim 25, further comprising forming a protection layer over the light emitting elements.

34. The method of claim 33, wherein forming the protection layer comprises:
forming an organic layer; and
forming an inorganic layer over the organic layer.

35. The method of claim 25, further comprising forming a dehydrating layer on the second substrate.

36. The method of claim 25, wherein the sealing member comprises a dehydrating material.

37. The method of claim 25, wherein the sealing member has an optical transmissivity of approximately 70% or less.

38. The method of claim 25, wherein forming the light emitting elements comprises:
forming a first electrode over the first substrate;
forming an organic light emitting layer over the first electrode; and
forming a second electrode over the light emitting layer.

39. The method of claim 38, further comprising forming an electrically insulating partition member between first electrodes.

40. The method of claim 39, wherein the second electrode is formed over the partition member.

41. The method of claim 39, wherein the sealing member is formed over the partition member.

42. A method of manufacturing a display device, comprising:
forming a plurality of light emitting elements over a first substrate;
forming a sealing member over a second substrate having portions exposing areas of the second substrate;
aligning the second substrate so that the portions overlie the light emitting elements; and
combining the first substrate and the second substrate.

43. A method of manufacturing a display device, comprising:
forming a plurality of light emitting elements over a first substrate;
forming a first sealing member over the first substrate;
forming a second sealing member over a second substrate;
aligning the first sealing member with the second sealing member; and
combining the first substrate and the second substrate so that light from the light emitting elements can pass through the second substrate .

44. The method of claim 43, further comprising:
contacting the first sealing member and the second sealing member; and
curing the first and the second sealing member by light or heat.
